(19) United States
(12) Patent Application Publication
(10) Pub. No.: US 2016/0204356 A1
(43) Pub. Date: Jul. 14, 2016

(54) ORGANIC LIGHT EMITTING DIODE

(71) Applicant: Samsung Display Co. Ltd., Yongin-City (KR)

(72) Inventors: Seung Gak YANG, Suwon-si (KR); Hee Yeon KIM, Suwon-si (KR)

(21) Appl. No.: 14/728,141

(22) Filed: Jun. 2, 2015

(30) Foreign Application Priority Data
Jan. 9, 2015 (KR) 10-2015-0003186

(51) Int. Cl. H01L 51/00; H01L 51/52; H01L 51/50

(52) U.S. Cl. CPC H01L 51/0071; H01L 51/0072; H01L 51/0085; H01L 51/5056; H01L 51/5072; H01L 51/5262

(57) ABSTRACT

An organic light emitting diode comprises a first electrode; a second electrode; and an organic layer comprising a first hole-transporting host, a second electron-transporting host, and a phosphorescent guest, and arranged between the first electrode and the second electrode, wherein the first hole-transporting host comprising at least one selected from the group consisting of compounds expressed by chemical formulas 1 and 2 below,

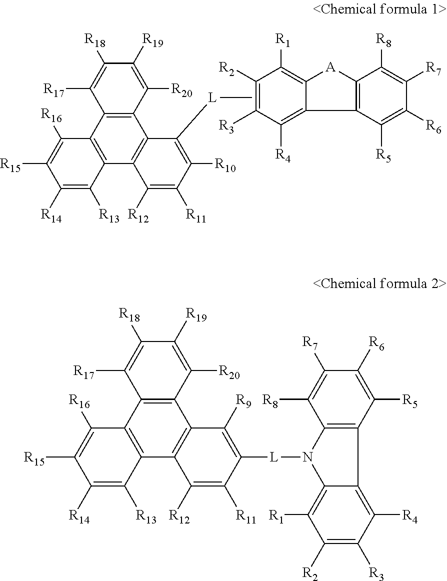

wherein in the chemical formulas 1 and 2, A, L, and R₁ to R₂₀ are defined the same as in the specification.

### CLAIM PRIORITY

This application makes reference to, incorporates into this specification the entire contents of, and claims all benefits accruing under 35 U.S.C. §119 from an application ORGANIC LIGHT EMITTING DIODE earlier filed in the Korean Intellectual Property Office on Jan. 9, 2015 and there duly assigned Serial No. 10-2015-0003186.

### BACKGROUND OF THE INVENTION

1. Field of the Invention

The present invention relates to an organic light emitting diode.

2. Description of the Related Art

An organic light emitting diode is a self-luminous device, and has the advantages of wide viewing angle, superior contrast, short response time, superior characteristics of luminance, driving voltage, and response speed, and polychrome. A general organic light emitting diode may have a structure in which an anode is formed on an upper portion of a substrate, and a hole transport layer (HTL), an emission layer (EML), an electron transport layer (ETL), and a cathode are successively formed on an upper portion of the anode. Here, the hole transport layer (HTL), the emission layer (EML), and the electron transport layer (ETL) are organic thin films made of organic compounds.

If a voltage is applied between the anode and the cathode, holes that are injected from the anode move to the emission layer (EML) through the hole transport layer (HTL), and electrons that are injected from the cathodes move to the emission layer (EML) through the electron transport layer (ETL). Carriers, such as holes and electrons, are recombined in the emission layer (EML) to generate excitons. As the excitons are transited from an excited state to a ground state, light is generated.

In this case, light emission during transition from the excited state to the ground state S0 through a singlet excited state S1 is called fluorescence, and light emission during transition from the excited state to the ground state S0 through a triplet excited state T1 is called phosphorescence.

In the case of the fluorescence, since the probability of the singlet excited state is 25% (the probability of the triplet excited state is 75%), the luminous efficiency is limited. In contrast, in the case of the phosphorescence, since 75% of the triplet excited state and 25% of the singlet excited state can be used, 100% internal quantum efficiency can be obtained in theory.

### SUMMARY OF THE INVENTION

Accordingly, one subject to be solved by the present invention is to provide an organic light emitting diode having high color purity.

Another subject to be solved by the present invention is to provide an organic light emitting diode having an improved luminous efficiency.

Still another subject to be solved by the present invention is to provide an organic light emitting diode having improved life characteristics.

Additional advantages, subjects, and features of the present invention will be set forth in part in the description which follows and in part will become apparent to those having ordinary skill in the art upon examination of the following or may be learned from practice of the invention.

In one aspect of the present invention, an organic light emitting diode may comprise a first electrode, a second electrode and an organic layer including a first hole-transporting host, a second electron-transporting host, and a phosphorescent guest, and arranged between the first electrode and the second electrode, wherein the first hole-transporting host may include at least one selected from the group consisting of compounds expressed by chemical formulas 1 and 2 below,

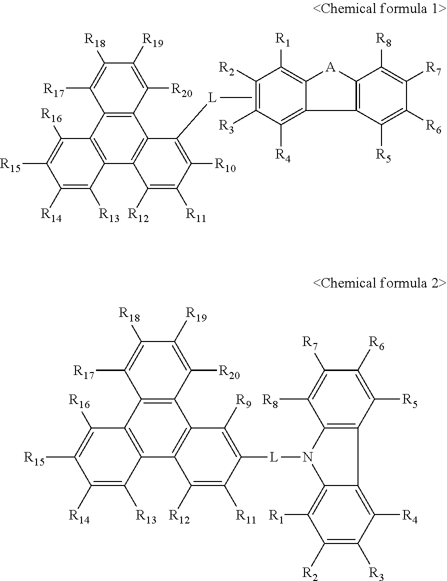

Wherein in the chemical formulas 1 and 2, A may be N or S; each of R₁ to R₂₀ may be independently one selected from the group consisting of hydrogen, halogen, a C₁-C₂₀ substituted or unsubstituted alkyl group, a C₁-C₂₀ substituted or unsubstituted cycloalkyl group, a C₁-C₂₀ substituted or unsubstituted alkoxy group, a C₃-C₂₀ substituted or unsubstituted heterocycle, a C₂-C₂₀ substituted or unsubstituted alkenyl group, a C₁-C₂₀ substituted or unsubstituted aryl group, a C₅-C₂₀ substituted or unsubstituted heteroaryl group, a C₃-C₂₀ substituted or unsubstituted heterocycloalkyl group, and a cyano group; and L may be one selected from the group consisting of a substituted or unsubstituted phenyl group, a C₃-C₂₀ substituted or unsubstituted heterocycle, a C₃-C₂₀ substituted or unsubstituted aryl group, a C₃-C₂₀ substituted or unsubstituted heteroaryl group.

According to the embodiments of the present invention, at least the following effects can be achieved.

An organic light emitting diode having high color purity can be provided.

An organic light emitting diode having high luminous efficiency can be provided.

An organic light emitting diode having improved life characteristics can be provided.

The effects according to the present invention are not limited to the contents as exemplified above, but further various effects are included in the description.

### BRIEF DESCRIPTION OF THE DRAWINGS

A more complete appreciation of the present invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a partial cross-sectional view of an organic light emitting diode according to an embodiment of the present invention.

### DETAILED DESCRIPTION OF THE INVENTION

Features of the inventive concept of accomplishing the same may be understood more readily by reference to the following detailed description of preferred embodiments and the accompanying drawings. The inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the inventive concept will only be defined by the appended claims.

In the drawings, the thickness of layers and regions are exaggerated for clarity. It will be understood that when an element or layer is referred to as being “on,” “connected to” or “coupled to” another element or layer, the element or layer can be directly on, connected or coupled to another element or layer, or one or more intervening elements or layers may be present. In contrast, when an element is referred to as being “directly on,” “directly connected to” or “directly coupled to” another element or layer, there are no intervening elements or layers present. As used herein, connected may refer to elements being physically, electrically, operably, and/or fluidly connected to each other.

Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof. Expressions such as “at least one of,” when preceding a list of elements, modify the entire list of elements and do not modify the individual elements of the list. Further, the use of “may” when describing embodiments of the present invention refers to “one or more embodiments of the present invention.” Also, the term “exemplary” is intended to refer to an example or illustration. As used herein, the terms “use,” “using,” and “used” may be considered synonymous with the terms “utilize,” “utilizing,” and “utilized,” respectively.

Hereinafter, embodiments of the present invention will be described with reference to the accompanying drawings and experimental examples.

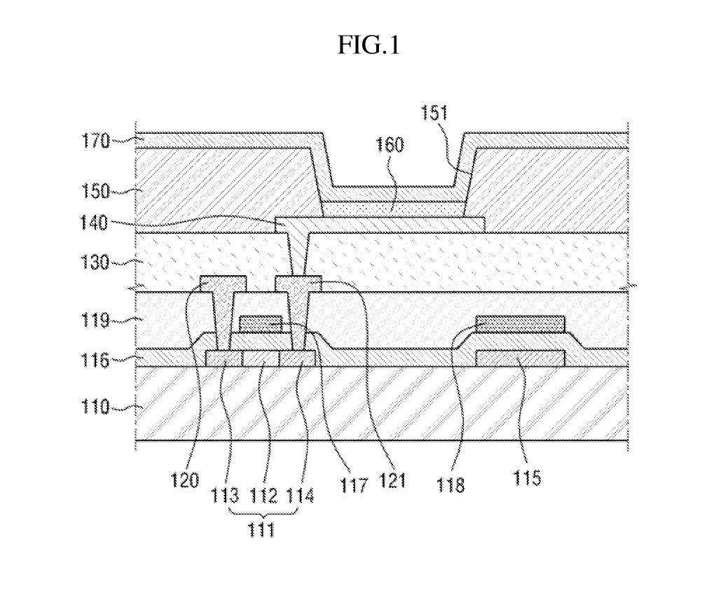

FIG. 1 is a partial cross-sectional view of an organic light emitting diode according to an embodiment of the present invention.

Referring to FIG. 1, an organic light emitting diode may include a substrate 110, an active layer 111, a lower electrode 115, a gate insulating layer 116, a gate electrode 117, an upper electrode 118, an interlayer insulating layer 119, a source electrode 120, a drain electrode 121, a planarization pattern 130, a first electrode 140, a pixel defining layer 150, an organic layer 160, and a second electrode 170.

The substrate 110 may be a transparent insulating substrate. The transparent insulating substrate may be made of a material, such as glass, quartz, or polymer resin. Examples of the polymer resin may include polyethersulphone (PES), polyacrylate (PA), polyarylate (PAR), polyetherimide (PEI), polyethylene napthalate (PEN), polyethylene terepthalate (PET), polyphenylene sulfide (PPS), polyallylate, polyimide (PI), polycarbonate (PC), cellulose triacetate (CAT or TAC), cellulose acetate propionate (CAP), and a combination thereof. In some embodiments, the transparent insulating substrate may be a flexible substrate that is made of a flexible material, such as polyimde (PI).

The active layer 111 may be arranged on the substrate 110, and may include a channel region 112, a source region 113 and a drain region 114 that are positioned on both sides of the channel region 112. The active layer 111 may be formed of silicon, for example, amorphous silicon or polysilicon, and the source region 113 and the drain region 114 may be doped with p-type or n-type impurities. The active layer 111 may be formed through a photolithography method, but is not limited thereto.

The lower electrode 115 may be arranged on the same layer as the active layer 111 on the substrate 110, and may be formed to be spaced apart from the active layer 111. The lower electrode 115 may be formed of the same material as the material of the source region 113 or the drain region 114. That is, the lower electrode 115 may be formed of silicon, and may include p-type or n-type impurities. The lower electrode 115 may be formed of a photolithography method, but is not limited thereto.

The gate insulating layer 116 may be formed on the substrate 110 to cover the active layer 111 and the lower electrode 115. The gate insulating layer 116 may electrically insulate the gate electrode 117 and the active layer 111 from each other. The gate insulating layer 116 may be made of an insulating material, for example, silicon oxide (SiOx), silicon nitride (SiNx), or metal oxide. The gate insulating layer 116 may be formed through a deposition method, but is not limited thereto.

The gate electrode 117 may be formed on the gate insulating layer 116. The gate electrode 117 may be formed on an upper portion of the channel region 112, i.e., in a position that overlaps the channel region 112 on the gate insulating layer 116. The gate electrode 117 may include metal, an alloy, metal nitride, conductive metal oxide, and a transparent conductive material. The gate electrode 117 may be formed through a photolithography method, but is not limited thereto.

The upper electrode 118 may be formed on the same layer as the layer of the gate electrode 117, and may be formed of the same material as the material of the gate electrode 117. The upper electrode 118 may be formed on an upper portion of the lower electrode 115, i.e., in a position that overlaps the lower electrode 115 on the gate insulating layer 116. The upper electrode 118 as described above may form a storage capacitor Cst together with the lower electrode 115 and the gate insulating layer 116. The storage capacitor Cst may be charged by a voltage that is applied to the gate electrode 117 of a thin film transistor TFT. The upper electrode 117 may be formed through a photolithography method, but is not limited thereto.

The interlayer insulating layer 119 may be formed on the gate insulating layer 116 to cover the gate electrode 117 and the upper electrode 118. The interlayer insulating layer 119 may be made of silicon compounds. For example, the interlayer insulating layer 119 may include silicon oxide, silicon nitride, silicon oxynitride, silicon carbonitride, and silicon oxycarbonate. The interlayer insulating layer 119 may serve to insulate the gate electrode 117 from the source electrode 120 and the drain electrode 121. The interlayer insulating layer 119 may be formed through a deposition method, but is not limited thereto.

The source electrode 120 and the drain electrode 121 may be formed on the interlayer insulating layer 119. The source electrode 120 may penetrate the interlayer insulating layer 119 and the gate insulating layer 116 to be connected to the source region 113 of the active layer 111, and the drain electrode 121 may penetrate the interlayer insulating layer 119 and the gate insulating layer 116 to be connected to the drain region 114.

The source electrode 120 and the drain electrode 121 may include metal, an alloy, metal nitride, conductive metal oxide, and a transparent conductive material. For example, the source electrode 120 and the drain electrode 121 may be made of aluminum, an alloy containing aluminum, aluminum nitride, silver, an alloy containing silver, tungsten, tungsten nitride, copper, an alloy containing copper, nickel, chrome, chrome nitride, molybdenum, an alloy containing molybdenum, titanium, titanium nitride, platinum, tantalum, tantalum nitride, neodymium, scandium, strontium ruthenium oxide, zinc oxide, indium tin oxide, tin oxide, indium oxide, gallium oxide, or indium zinc oxide. The source electrode 120 and the drain electrode 121 may be formed through a photolithography method, but is not limited thereto.

The source electrode 120 and the drain electrode 121 may form a thin film transistor TFT together with the active layer 111 and the gate electrode 117. The thin film transistor TFT may be a driving transistor which supplies current that corresponds to a voltage that is applied to the gate electrode 117 to a light emitting diode (a portion composed of 140, 160, and 170). Although not illustrated, the thin film transistor may be connected to a switching transistor. The switching transistor may apply a voltage which corresponds to a data signal that is supplied through a data line (not illustrated) to the thin film transistor TFT in response to a gate signal that is supplied through a gate line (not illustrated).

The planarization pattern 130 may be formed on the interlayer insulating layer 119 to cover the source electrode 120 and the drain electrode 121. The planarization pattern 130 may have a flat surface. The planarization pattern 130 may be arranged in the unit of a pixel P. According to circumstances, the planarization pattern 130 may be integrally formed on the interlayer insulating layer 119.

The first electrode 140 may be formed for each pixel on the substrate 110. The first electrode 140 may be an anode electrode which receives a signal that is applied to the drain electrode 121 of the thin film transistor TFT and provides holes to the organic layer 160 or a cathode electrode that provides electrons to the organic layer 160.

The first electrode 140 may be used as a transparent electrode or a reflective electrode. In the case where the first electrode 140 is used as the transparent electrode, it may be formed of ITO (Indium Tin Oxide), IZO (Indium Zinc Oxide), ZnO (Zinc Oxide), or In₂O₃. Further, in the case where the first electrode 140 is used as the reflective electrode, it may be configured by forming a reflective layer that is made of Ag, Mg, Al, Pt, Pd, Au, Ni, Nd, Ir, Cr, or a compound thereof and forming ITO, IZO, ZnO, or In₂O₃ thereon. The first electrode 140 may be formed through a photolithography process, but is not limited thereto.

The pixel defining layer 150 may partition respective pixels on the substrate 110, and may have an opening 151 that exposes the first electrode 140. Accordingly, the pixel defining layer 150 may make the organic layer 160 be formed on the first electrode 140 through the opening 151. The pixel defining layer 150 may be made of an insulating material. Specifically, the pixel defining layer 150 may be formed to include at least one organic material selected from the group including benzo cyclo butene (BCB), polyimide (PI), poly amaide (PA), acrylic resin, and phenol resin. Further, as another example, the pixel defining layer 150 may be formed to include an inorganic material, such as silicon nitride. The pixel defining layer 150 may be formed through a photolithography process, but is not limited thereto.

In an unlimited example, when the organic layer 160 is formed using an inkjet printing method or a nozzle printing method, the pixel defining layer 150 may be formed of an insulating material that can make a contact angle of the organic layer 160 to the pixel defining layer 150 be larger than a contact angle of the organic layer 160 to the first electrode 140. For example, the pixel defining layer 150 may be formed of an insulating material that makes the contact angle of the organic layer 160 to the pixel defining layer 150 be equal to or larger than 40°.

The organic layer 160 may be formed on the first electrode 140 that is exposed through the opening 151 of the pixel defining layer 150. The organic layer 160 may include an organic light emitting layer that emits light through recombination of the holes provided from the first electrode 140 and the electrons provided from the second electrode 170. More specifically, if the holes and the electrons are provided to the organic light emitting layer, the holes and the electrons are combined to generate excitons, and as the excitons are transited from an excited state to a ground state, light is emitted.

The organic light emitting layer may be implemented by a red light emitting layer that emits red light, a green light emitting layer that emits green light, and a blue light emitting layer that emits blue light.

The organic light emitting layer may be formed using an inkjet printing method or a nozzle printing method, but is not limited thereto. In the case where the organic light emitting layer is formed using the inkjet printing method or the nozzle printing method, the organic light emitting layer may be formed by discharging an organic light emitting ink that includes solid content of the organic light emitting material and a solvent onto the first electrode 140 that is exposed through the opening 151 of the pixel defining layer 150 and drying the organic light emitting ink through a separate drying process in a vacuum atmosphere.

The organic light emitting layer may include a first hole-transporting host, a second electron-transporting host, and a phosphorescent guest. The first hole-transporting host and the second electron-transporting host may be co-deposited.

The first hole-transporting host may include at least one selected from the group consisting of compounds expressed by chemical formulas 1 and 2 below.

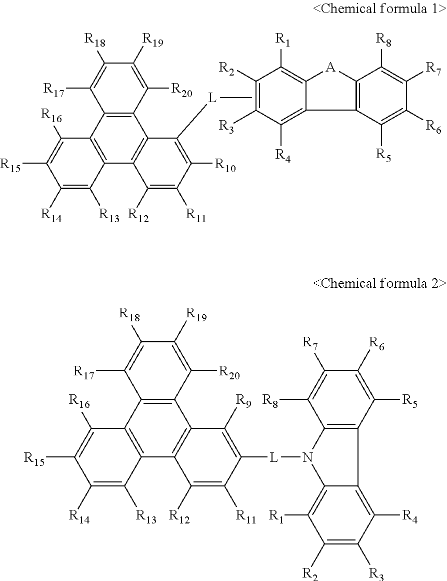

In the chemical formulas 1 and 2 as described above, A may be N or S; each of R₁ to R₂₀ may independently be one selected from the group consisting of hydrogen, halogen, a C₁-C₂₀ substituted or unsubstituted alkyl group, a C₁-C₂₀ substituted or unsubstituted cycloalkyl group, a C₁-C₂₀ substituted or unsubstituted alkoxy group, a C₃-C₂₀ substituted or unsubstituted heterocycle, a C₂-C₂₀ substituted or unsubstituted alkenyl group, a C₁-C₂₀ substituted or unsubstituted aryl group, a C₅-C₂₀ substituted or unsubstituted heteroaryl group, a C₃-C₂₀ substituted or unsubstituted heterocycloalkyl group, and a cyano group; and L may be one selected from the group consisting of a substituted or unsubstituted phenyl group, a C₃-C₂₀ substituted or unsubstituted heterocycle, a C₃-C₂₀ substituted or unsubstituted aryl group, a C₃-C₂₀ substituted or unsubstituted heteroaryl group.

In an unlimited example, R₁ to R₂₀ may be combined with adjacent functional groups and may form one selected from the group consisting of a C₅-C₂₀ fused aliphatic ring, a C₅-C₂₀ fused aromatic ring, a C₅-C₂₀ fused hetero aliphatic ring, and a C₅-C₂₀ fused hetero aromatic ring.

In an unlimited example, in the chemical formulas 1 and 2, the alkyl group, the cycloalkyl group, the alkoxy group, the heterocycle, the alkenyl group, the aryl group, the heteroaryl group, or the heterocycloalkyl group of the R₁ to R₂₀ may independently substitute a hydrogen atom with one substituent selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, and a C₁-C₂₀ haloalkyl group.

In an unlimited example, in the chemical formulas 1 and 2, the phenyl group, the heterocycle, the aryl group, or the heteroaryl group of the L may independently have one substituent selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, a C₁-C₂₀ haloalkyl group, and a cyano group.

In an unlimited example, the one substituent may be combined with each other to form one selected from the group consisting of a C₅-C₂₀ fused aliphatic ring, a C₅-C₂₀ fused aromatic ring, a C₅-C₂₀ fused hetero aliphatic ring, and a C₅-C₂₀ fused hetero aromatic ring.

In an unlimited example, the L may be one selected from the group consisting of compounds expressed by chemical formulas 3 to 9 below.

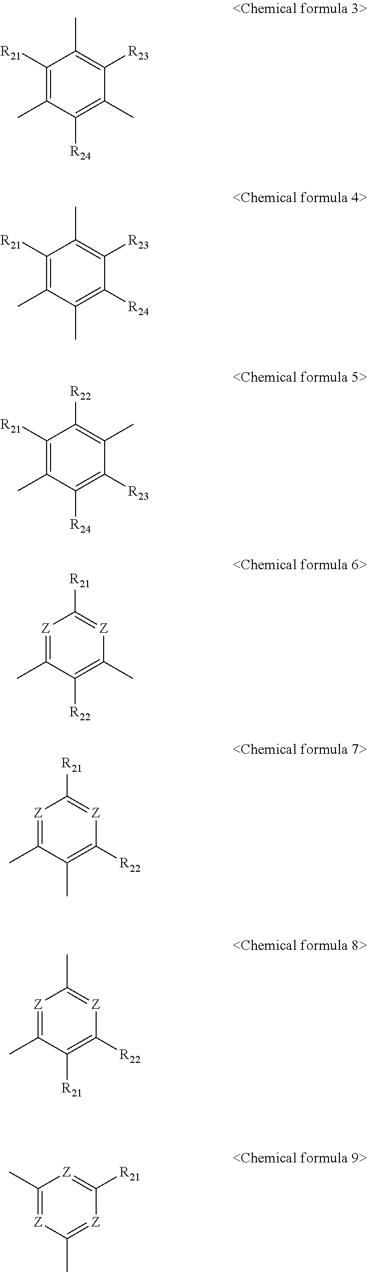

In the chemical formulas 3 to 9 as described above, each of R₂₁ to R₂₄ may independently be one selected from the group consisting of hydrogen, halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, a C₁-C₂₀ haloalkyl group, and a cyano group; at least one of a plurality of Z may be a nitrogen atom, and the remainder may be a carbon atom; and a hydrogen atom attached to Z may be unsubstituted or may be substituted with one selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, a C₁-C₂₀ haloalkyl group, and a cyano group.

In an unlimited example, the first hole-transporting host may be one selected from the group consisting of compounds expressed by chemical formulas 10 to 44 below. In the chemical formulas 10 to 44, A may be N or S.

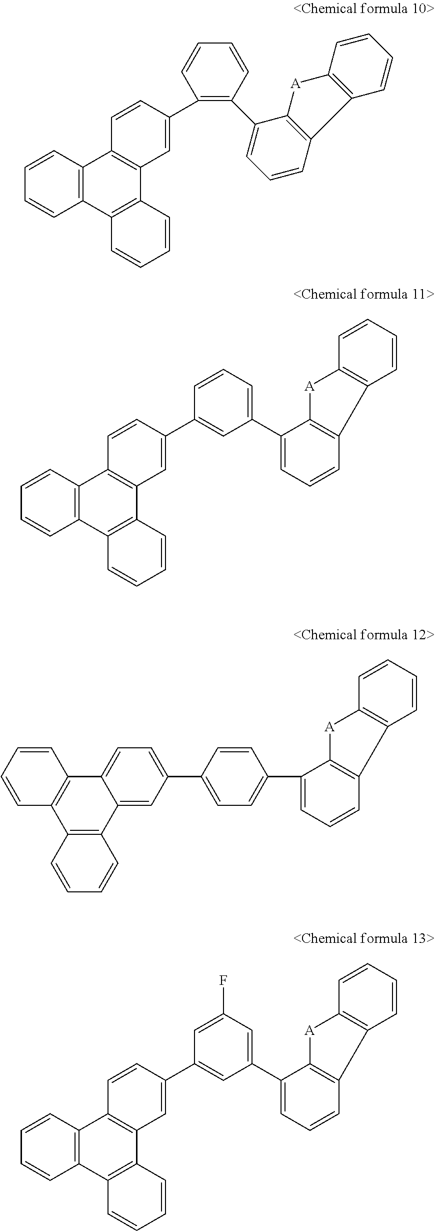

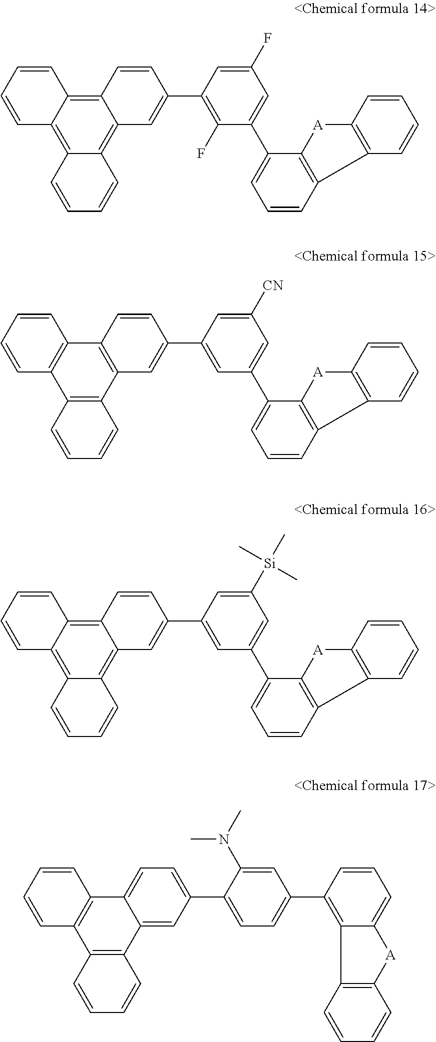

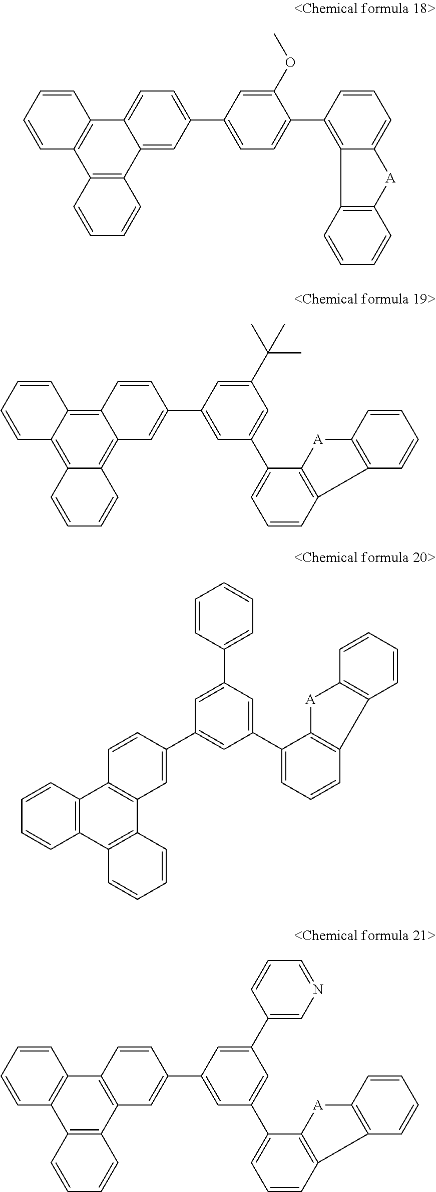

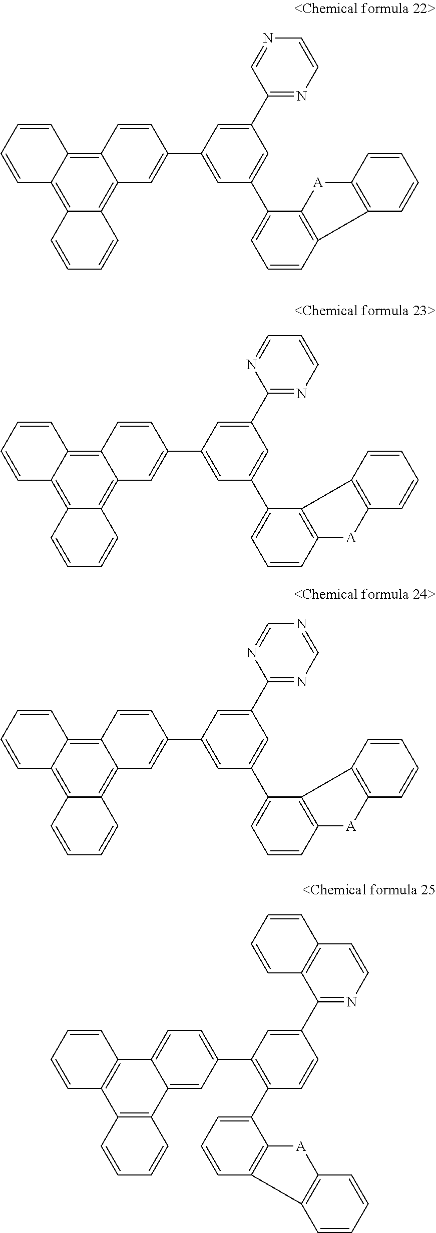

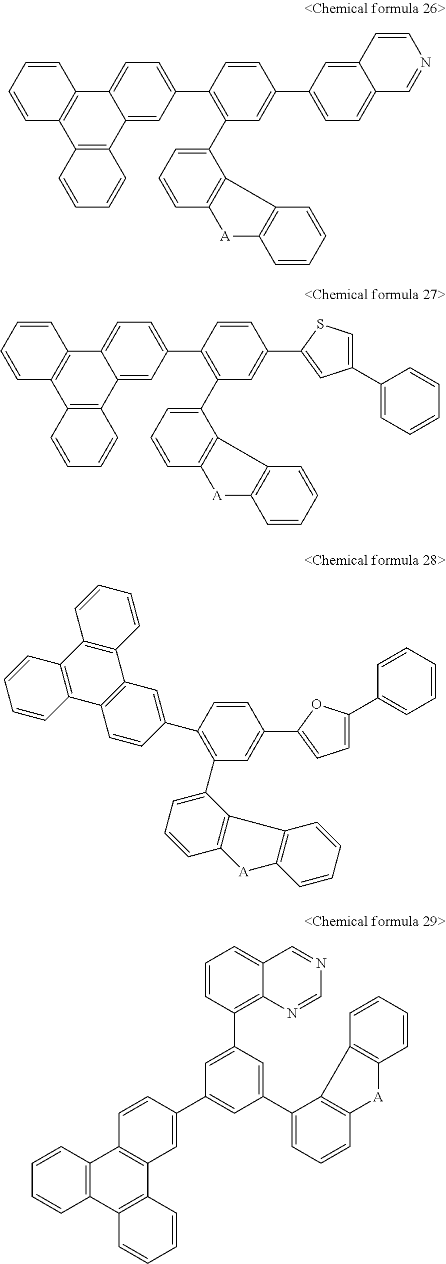

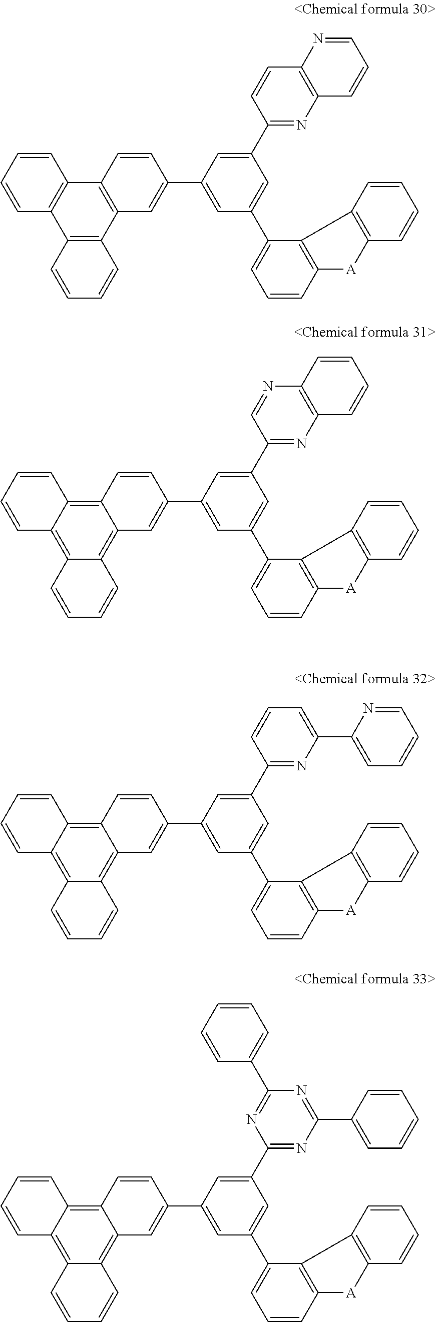

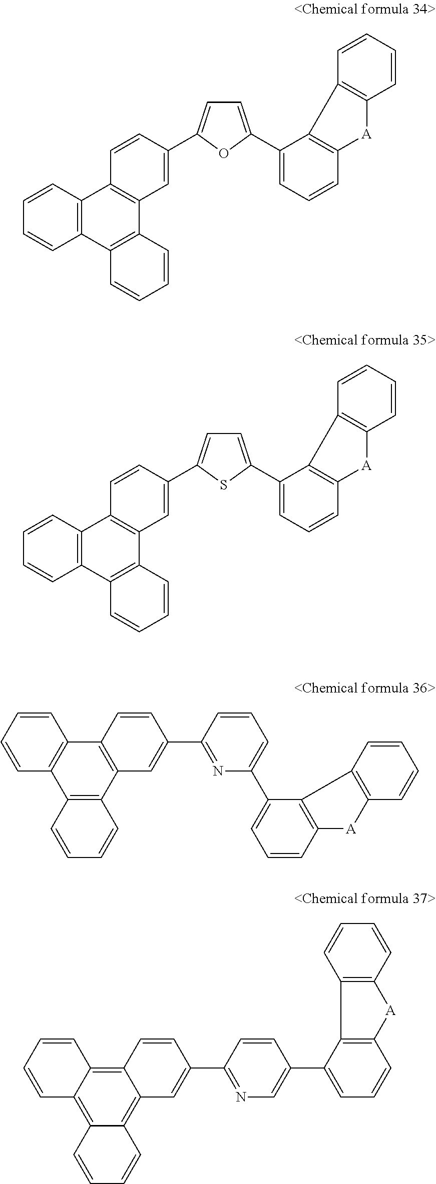

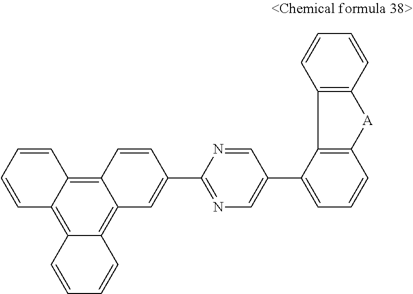

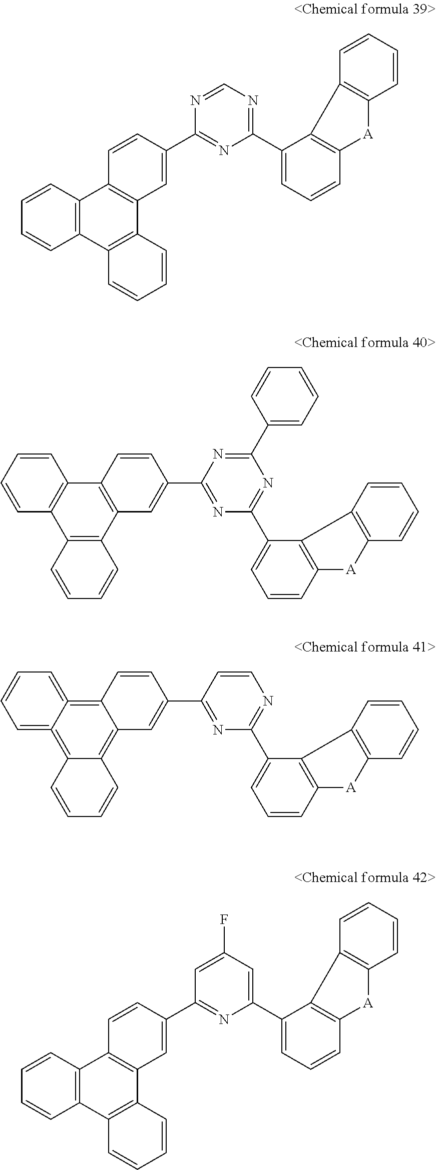

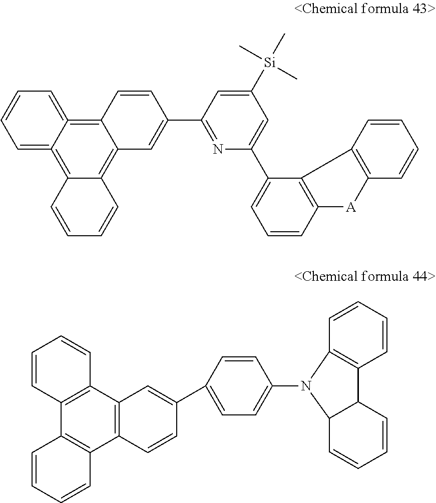

In an unlimited example, the second electron-transporting host may include at least one selected from the group consisting of compounds expressed by chemical formulas 45 to 48 below.

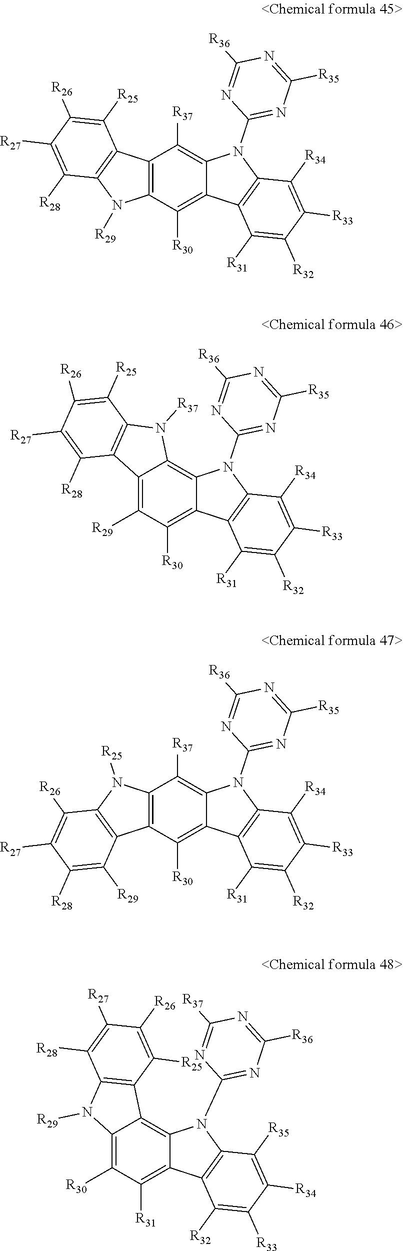

In the chemical formulas 45 to 48, each of R₂₅ to R₃₇ may independently be one selected from the group consisting of a hydrogen atom, a cyano group, a hydroxyl group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group.

In an unlimited example, the phosphorescent guest may include a compound expressed by chemical formula 49.

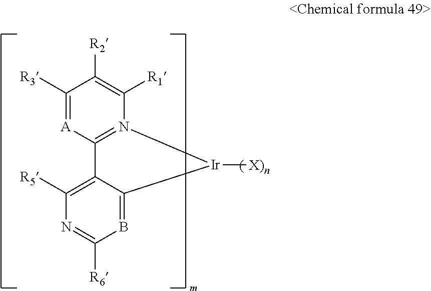

In the chemical formula 49, A may be —C(R′₄)— or —N—; B may be —C(R′₇)— or —N—; each of R′₁ to R′₇ may independently be one selected from the group consisting of a hydrogen atom, a cyano group, a hydroxy group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group; two or more substitutes selected among R′₁ to R′₄, R′₄ and R′₅, and R′₆ and R′₇ may be connected to each other to form saturated or unsaturated carbon chain or saturated or unsaturated hetero chain, and X may be a monovalence anionic bidentate ligand; m may be 2 or 3, n may be 0 or 1, and the sum of m and n may be 3. Therefore, two or more substitutes selected among R′₁ to R′₄ are connected to each other to form saturated or unsaturated carbon chain or saturated or unsaturated hetero chain, R′₄ and R′₅ are connected to each other to form saturated or unsaturated carbon chain or saturated or unsaturated hetero chain, R′₆ and R′₇ are connected to each other to form saturated or unsaturated carbon chain or saturated or unsaturated hetero chain.

In an unlimited example, the phosphorescent guest may include at least one selected from the group consisting of compounds expressed by chemical formulas 50 and 51 below.

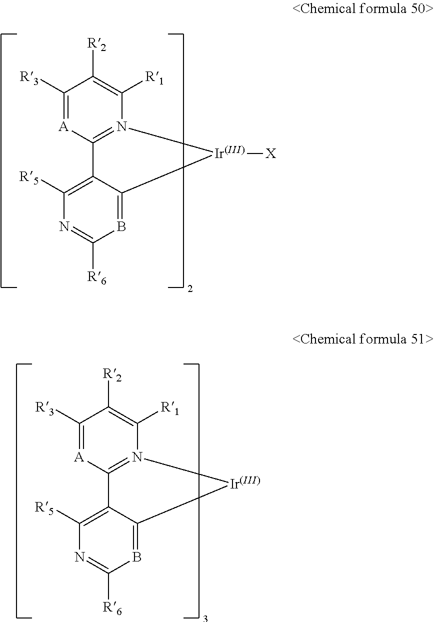

In the chemical formulas 50 and 51, A may be —C(R′₄)— or —N—; B may be —C(R′₇)— or —N—; each of R′₁ to R′₇ may independently be one selected from the group consisting of a hydrogen atom, a cyano group, a hydroxy group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group; two or more substitutes selected among R′₁ to R′₄, R′₄ and R′₅, and R′₆ and R′₇ may be connected to each other to form saturated or unsaturated carbon chain or saturated or unsaturated hetero chain, and X may be a monovalence anionic bidentate ligand; m may be 2 or 3, n may be 0 or 1, and the sum of m and n may be 3. Therefore, two or more substitutes selected among R′₁ to R′₄ are connected to each other to form saturated or unsaturated carbon chain or saturated or unsaturated hetero chain, R′₄ and R′₅ are connected to each other to form saturated or unsaturated carbon chain or saturated or unsaturated hetero chain, R′₆ and R′₇ are connected to each other to form saturated or unsaturated carbon chain or saturated or unsaturated hetero chain.

In an unlimited example, X may be one selected from the group consisting of compounds expressed by chemical formulas 52 to 63 below.

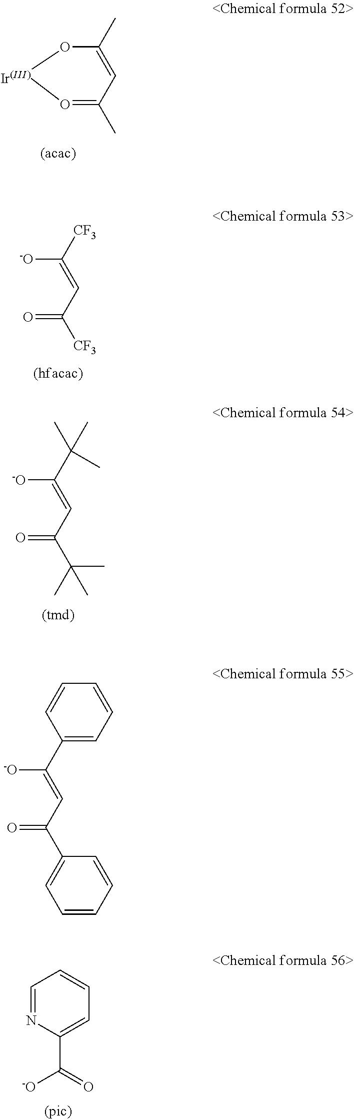

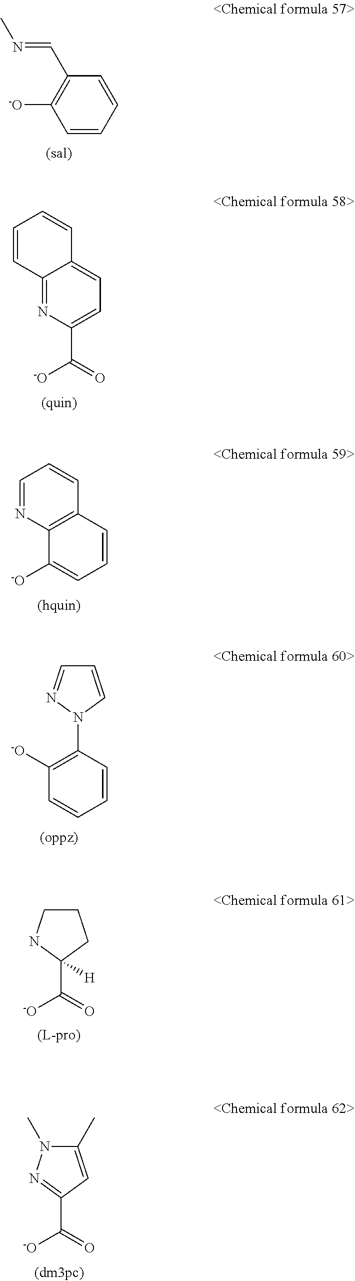

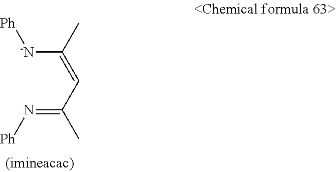

In an unlimited example, the first hole-transporting host content may be equal to or higher than 50 wt % and equal to or lower than 78%, and the second electron-transporting host content may be equal to or higher than 10 wt % and equal to or lower than 40 wt %. The phosphorescent guest content may be equal to or higher than 1 wt % and equal to or lower than 20 wt %.

According to circumstances, the organic light emitting layer may further include, for example, Alq3 (tris-(8-hydroyquinolato) aluminum(III)), CBP(4,4′-N,N′-dicarbazole-biphenyl), PVK(poly(N-vinylcarbazole)), ADN(9,10-Bis(2-naphthalenyl)anthracene), TCTA(4,4′,4″-tris(Ncarbazolyl)triphenylamine), TPBi(1,3,5-tris(N-phenylbenzimiazole-2-yl)benzene), TBADN(2-(t-butyl)-9, 10-bis (20-naphthyl) anthracene), DSA(distyrylarylene), CDBP(4,4′-Bis(9-carbazolyl)-2,2′-Dimethyl-biphenyl), and MADN(2-Methyl-9,10-bis(naphthalen-2-yl)anthracene) as the host.

According to circumstances, the organic light emitting layer may be selected from fluorescent materials that include any one selected from the group consisting of spiro-DPVBi(spiro-4,′-bis(2,2′-diphenylvinyl)1,1′-biphenyl), spiro-based polymer, and PPV(poly p-phenylene vinylene))-based polymer. Further, as the phosphorescent materials, F2Irpic(bis[2-(4,6-difluorophenyl)pyridinato-N,C2′]iridium picolinate), (F2ppy)2Ir(tmd)(bis[2-(4,6-difluorophenyl)pyridinato-N,C2′]iridium 2,2,6,6-tetramethylheptane-3,5-dione), and Ir(dfppz)3(tris[1-(4,6-difluorophenyl)pyrazolate-N,C2′]iridium) may be further included.

In an unlimited example, the organic layer 160 may further include a hole injection layer and a hole transport layer formed between the first electrode 140 and the organic light emitting layer in addition to the organic light emitting layer. The hole injection layer and the hole transport layer may be formed using an inkjet printing method or a nozzle printing method, but are not limited thereto.

In an unlimited example, the hole injection layer may be arranged on the first electrode 140, and serves to heighten hole injection efficiency from the first electrode 140 to the organic light emitting layer side. Specifically, the hole injection layer makes the holes be injected more effectively through lowering of energy barriers.

In an unlimited example, the hole injection layer may include a phthalocyanine compound, such as copper phthalocyanine (CuPc), m-MTDATA(4,4′,4″-tris(N-3-methylphenyl-N-phenylamino)triphenylamine), TDATA(4,4′,4″-tris(diphenylamino)triphenylamine), 2-TNATA(4,4′,4″-tris[2-naphthyl(phenyl)-amino]triphenyl-amine), Pani/DBSA (Polyaniline/Dodecylbenzenesulfonic acid), PEDOT/PSS(Poly(3,4-ethylene dioxythiophene)/Polystyrene sulfonate), PANI/CSA (Polyaniline/Camphorsulfonic acid) or PANI/PSS (Polyaniline/Polystyrene sulfonate).

In an unlimited example, the hole transport layer may be arranged on the hole injection layer, and serves to transport the holes that are injected to the hole injection layer to the organic light emitting layer.

In an unlimited example, the hole transport layer may have an optimized hole transport efficiency in the case where the highest occupied molecular energy (HOMO) is substantially lower than a work function of a material that forms the first electrode 140 and is substantially higher than the higheset occupied molecular energy (HOMO) of the organic light emitting layer.

In an unlimited example, the hole transport layer may include, for example, NPD(4,4′-bis[N-(1-napthyl)-N-phenyl-amino]biphenyl), TPD(N,N′-diphenyl-N,N′-bis[3-methylphenyl]-1,1′-biphenyl-4,4′-diamine), s-TAD(2,2′,7,7′-tetrakis-(N,N-diphenylamino)-9,9′-spirobifluoren), and m-MTDATA(4,4′,4″-tris(N-3-methylphenyl-N-phenylamino)triphenylamine), but is not limited thereto.

Further, the organic layer 160 may further include an electron injection layer and an electron transport layer that are formed between the organic light emitting layer and the second electrode 170.

In an unlimited example, the electron transport layer may be arranged on the organic light emitting layer, and serves to transport the electrons injected from the electron injection layer to the organic light emitting layer.

In an unlimited example, the electron transport layer may include Alq3(tris-(8-hydroxyquinolato) aluminum(III)), TPBi(1,3,5-tris(N-phenylbenzimiazole-2-yl)benzene), BCP(2,9-dimethyl-4,7-diphenyl-1,10-phenanthroline), Bphen(4,7-diphenyl-1,10-phenanthroline), TAZ(3-(Biphenyl-4-yl)-5-(4-tert-butylphenyl)-4-phenyl-4H-1,2,4-triazole), NTAZ(4-(naphthalen-1-yl)-3,5-diphenyl-4H-1,2,4-triazole), tBu-PBD(2-(4-biphenylyl)-5-(4-tert-butyl-phenyl)-1,3,4-oxadiazole), BAlq(Bis(2-methyl-8-quinolinolato-N1,O8)-(1,1′-Biphenyl-4-olato)aluminum), Bebq2(Bis(10-hydroxybenzo[h]quinolinato)beryllium), ADN(9,10-bis(2-naphthyl)anthracene), and a mixture thereof, but is not limited thereto.

In an unlimited example, the electron injection layer may be arranged on the electron transport layer, and serves to heighten the electron injection efficiency from the second electrode 170 to the organic light emitting side.

In an unlimited example, the electron injection layer may be made of a lanthanum group metal, such as LiF, LiQ (Lithium Quinolate), Li₂O, BaO, NaCl, CsF, or Yb, or metal halide, such as RbCl or RbI, but is not limited thereto. The electron injection layer may be made of a material in which the above-describe material and insulating organo metal salt are mixed. The organo metal salt may be a material having an energy band gap of about 4 eV or more. Specifically, the organo metal salt may include, for example, metal acetate, metal benzoate, metal acetoacetate, metal acetylacetonate, or metal stearate.

In an unlimited example, the hole injection layer and the hole transport layer may be formed using a deposition method, but are not limited thereto. Of course, in the case where the first electrode 140 is a cathode electrode and the second electrode 170 is an anode electrode, the electron injection layer and the electron transport layer may be interposed between the first electrode 140 and the organic light emitting layer, and the hole injection layer and the hole transport layer may be interposed between the organic light emitting layer and the second electrode 170.

In an unlimited example, the second electrode 170 may be formed on the organic layer 160, and may be a cathode electrode that provides electrons or an anode electrode that provides holes. In the same manner as the first electrode 110, the second electrode 170 may be a transparent electrode or a reflective electrode. The second electrode 170 may be formed through a deposition process, but is not limited thereto.

Although not illustrated, the organic light emitting diode may further include an encapsulation substrate (not illustrated) that is arranged on the upper portion of the second electrode 170. The encapsulation substrate may be an insulating substrate. Spacers (not illustrated) may be arranged between the second electrode 170 and the encapsulation layer on the pixel defining layer 150. In some embodiments of the present invention, the encapsulation substrate may be omitted. In this case, an encapsulation layer that is made of an insulating material may cover and protect the whole structure.

Hereinafter, based on experimental examples, driving voltage, emission efficiency, and color coordinate measurement results between experimental samples 1 to 3 and a comparative sample will be described in detail.

<Production of Experimental Sample 1>

As an anode, 15 Ω/cm² (500 Å) ITO glass substrate produced by Corning Inc. was cut to size of 50 mm×50 mm×0.5 mm, and ultrasonic cleaning was performed for 10 minutes, respectively, using isopropyl alcohol and DI water. Thereafter, the glass substrate was irradiated with UV light, exposed to ozone, cleaned, and then mounted on a vacuum deposition device.

2-TNATA was vapor-deposited on an upper portion of the glass substrate to form a hole injection layer with a thickness of 600 Å, and then NPB was vapor-deposited on an upper portion of the hole injection layer to form a hole transport layer with a thickness of 300 Å. An organic light emitting layer was formed on an upper portion of the hole transport layer with a thickness of 300 Å.

The organic light emitting layer was formed by simultaneously depositing a compound expressed by chemical formula 51 below as a blue phosphorescent dopant, a compound expressed by chemical formula 10 as the first hole-transporting host, and a compound expressed by chemical formula 45 below as the second electron-transporting host in the weight ratio of 10:65:25.

Then, Alq3 was vapor-deposited on the upper portion of the organic light emitting layer to form an electron transport layer with a thickness of 300 Å. Al was vapor-deposited on the upper portion of the electron transport layer to form a cathode with a thickness of 1200 Å, so as to complete the manufacturing of an organic light emitting diode.

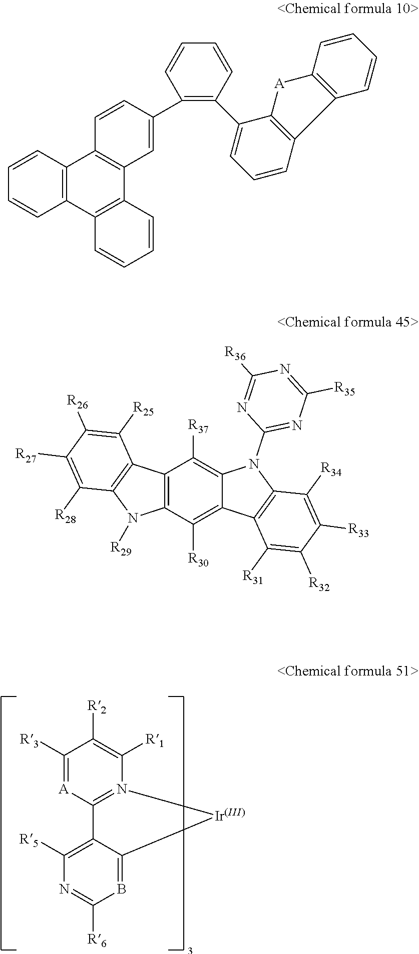

In the chemical formula 10, A may be —N—.

In the chemical formula 45, R₂₅ to R₃₇ may be independently hydrogen atoms.

In the chemical formula 51, R′₁ to R′₆ may be independently hydrogen atoms, and A and B may be —N—, respectively.

<Production of Experimental Sample 2>

An organic light emitting diode was produced using the same method as the method of experimental sample 1 except that the weight ratio of a blue phosphorescent dopant, a first hole-transporting host, and a second electron-transporting host was set to be the weight ratio of 20:55:25.

<Production of Experimental Sample 3>

An organic light emitting diode was produced using the same method as the method of experimental sample 1 except that the weight ratio of a blue phosphorescent dopant, a first hole-transporting host, and a second electron-transporting host was set to the weight ratio of 5:60:35.

<Production of Comparative Sample>

CBP(4,4′-N,N′-dicarbazole-biphenyl) was used as a host, and FIrpic(bis[2-(4,6-difluorophenyl)pyridinato-N,C2′]iridium picolinate) was used as a blue phosphorescent dopant. An organic light emitting diode was produced using the same method as the method of experimental sample 1 except that the weight ratio of CBP and Firpic was set to 7:3.

<Measurement of Driving Voltage>

The driving voltage, emission efficiency, and color coordinates of the comparative example and experimental samples 1 to 3 were confirmed. The results are shown in tables 1 to 3.

TABLE 1

| | Driving Voltage (V) |
|---|---|
| Example 1 | 5.8 |
| Example 2 | 6.0 |
| Example 3 | 5.9 |
| Comparative Example | 8.2 |
| (CBP:FIrpic) | |

TABLE 2

| | Emission Efficiency (cd/A) |
|---|---|
| Example 1 | 9.2 |
| Example 2 | 9.5 |
| Example 3 | 8.6 |
| Comparative Example | 4.2 |
| (CBP:FIrpic) | |

TABLE 3

| | Color Coordinates |
|---|---|
| Example 1 | (0.15, 0.16) |
| Example 2 | (0.15, 0.18) |
| Example 3 | (0.16, 0.17) |
| Comparative Example | (0.16, 0.37) |
| (CBP:FIrpic) | |

Although preferred embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. An organic light emitting diode comprising:
a first electrode;
a second electrode; and
an organic layer arranged between the first electrode and the second electrode comprising a first hole-transporting host, a second electron-transporting host, and a phosphorescent guest, wherein
the first hole-transporting host comprises at least one selected from the group consisting of compounds expressed by chemical formulas 1 and 2 below, 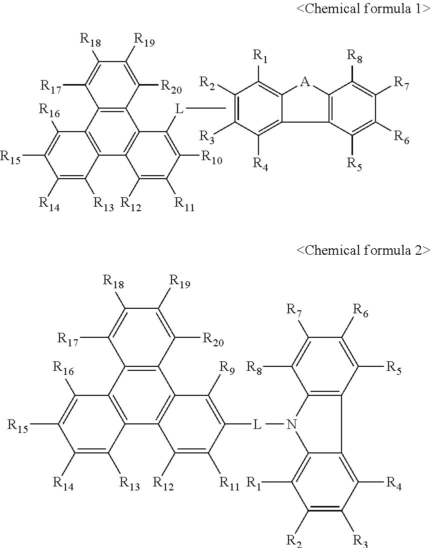
wherein A is N or S;
each of R₁ to R₂₀ is independently one selected from the group consisting of hydrogen, halogen, a C₁-C₂₀ substituted or unsubstituted alkyl group, a C₁-C₂₀ substituted or unsubstituted cycloalkyl group, a C₁-C₂₀ substituted or unsubstituted alkoxy group, a C₃-C₂₀ substituted or unsubstituted heterocycle, a C₂-C₂₀ substituted or unsubstituted alkenyl group, a C₁-C₂₀ substituted or unsubstituted aryl group, a C₅-C₂₀ substituted or unsubstituted heteroaryl group, a C₃-C₂₀ substituted or unsubstituted heterocycloalkyl group, and a cyano group; and
L is one selected from the group consisting of a substituted or unsubstituted phenyl group, a C₃-C₂₀ substituted or unsubstituted heterocycle, a C₃-C₂₀ substituted or unsubstituted aryl group, a C₃-C₂₀ substituted or unsubstituted heteroaryl group.

2. The organic light emitting diode of claim 1, wherein the R₁ to R₂₀ are combined with adjacent functional groups and form one selected from the group consisting of a C₅-C₂₀ fused aliphatic ring, a C₅-C₂₀ fused aromatic ring, a C₅-C₂₀ fused hetero aliphatic ring, and a C₅-C₂₀ fused hetero aromatic ring.

3. The organic light emitting diode of claim 1, wherein the alkyl group, the cycloalkyl group, the alkoxy group, the heterocycle, the alkenyl group, the aryl group, the heteroaryl group, or the heterocycloalkyl group of the R₁ to R₂₀ independently has one substituent selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, and a C₁-C₂₀ haloalkyl group.

4. The organic light emitting diode of claim 1, wherein the phenyl group, the heterocycle, the aryl group, or the heteroaryl group of the L independently has one substituent selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, a C₁-C₂₀ haloalkyl group, and a cyano group.

5. The organic light emitting diode of claim 4, wherein the one substituent is combined with each other to form one selected from the group consisting of a C₅-C₂₀ fused aliphatic ring, a C₅-C₂₀ fused aromatic ring, a C₅-C₂₀ fused hetero aliphatic ring, and a C₅-C₂₀ fused hetero aromatic ring.

6. The organic light emitting diode of claim 1, wherein the L is one selected from the group consisting of compounds expressed by chemical formulas 3 to 9 below: 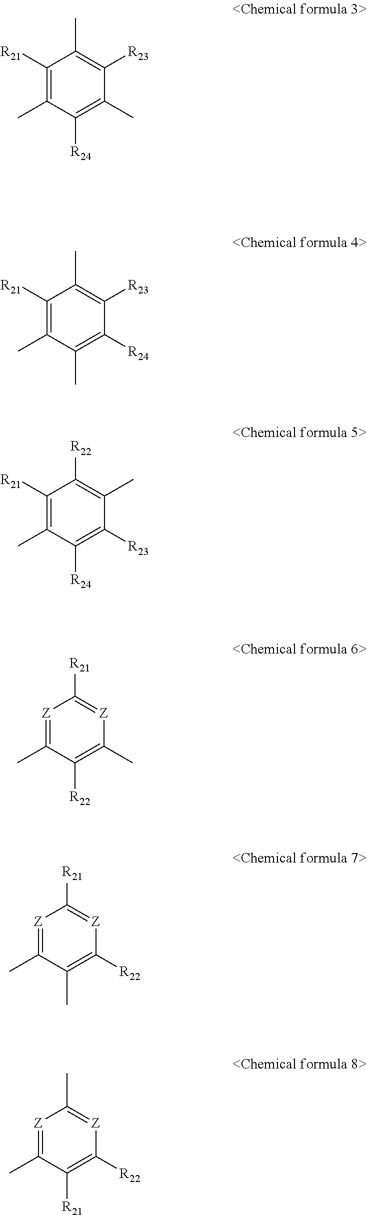 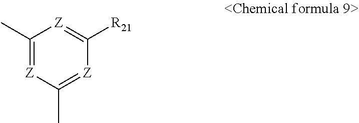
wherein in the chemical formulas 3 to 9, each of R₂₁ to R₂₄ is independently one selected from the group consisting of hydrogen, halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, a C₅-C₂₀ aryloxy group, a C₂-C₂₀ alkenyl group, a C₁-C₂₀ alkyl amine group, a C₅-C₂₀ aryl silyl group, a C₁-C₂₀ haloalkyl group, and a cyano group;
at least one of a plurality of Z is a nitrogen atom, and the remainder is a carbon atom; and
a hydrogen atom attached to Z is unsubstituted or substituted with one selected from the group consisting of halogen, a C₁-C₂₀ alkyl group, a C₃-C₂₀ heterocycle, a C₅-C₂₀ heteroaryl group, a C₁-C₂₀ alkoxy group, a C₃-C₂₀ cycloalkyl group, a C₅-C₂₀ aryl group, aryloxy, a C₅-C₂₀ group, a C₂-C₂₀ alkenyl group, a C₁-C₂₀ alkyl amine group, a C₅-C₂₀ aryl silyl group, a C₁-C₂₀ haloalkyl group, and a cyano group.

7. The organic light emitting diode of claim 1, wherein the first hole-transporting host is one selected from the group consisting of compounds expressed by chemical formulas 10 to 44 below, 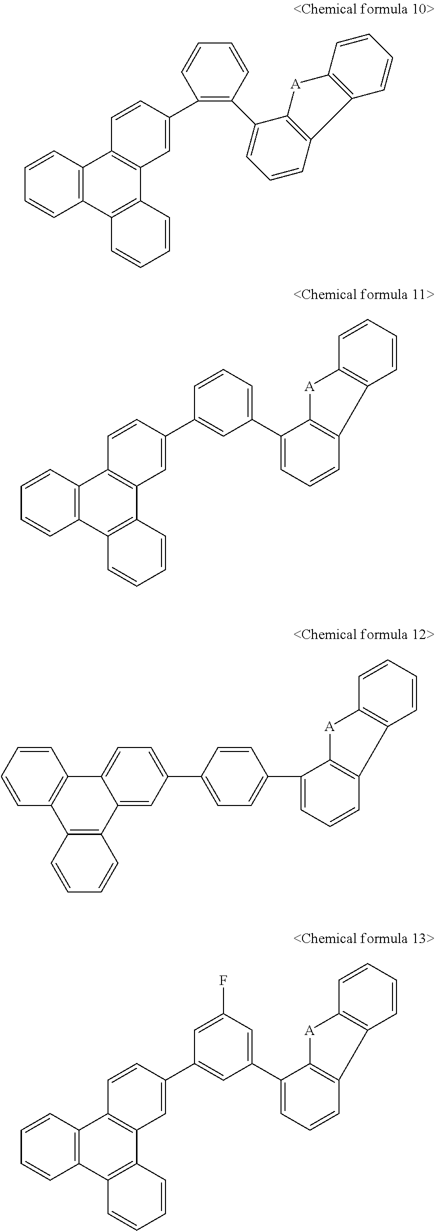 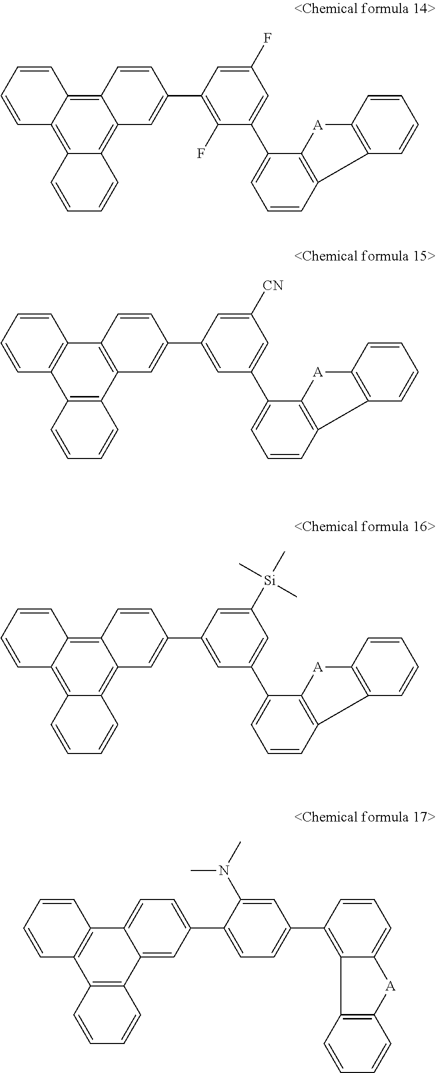 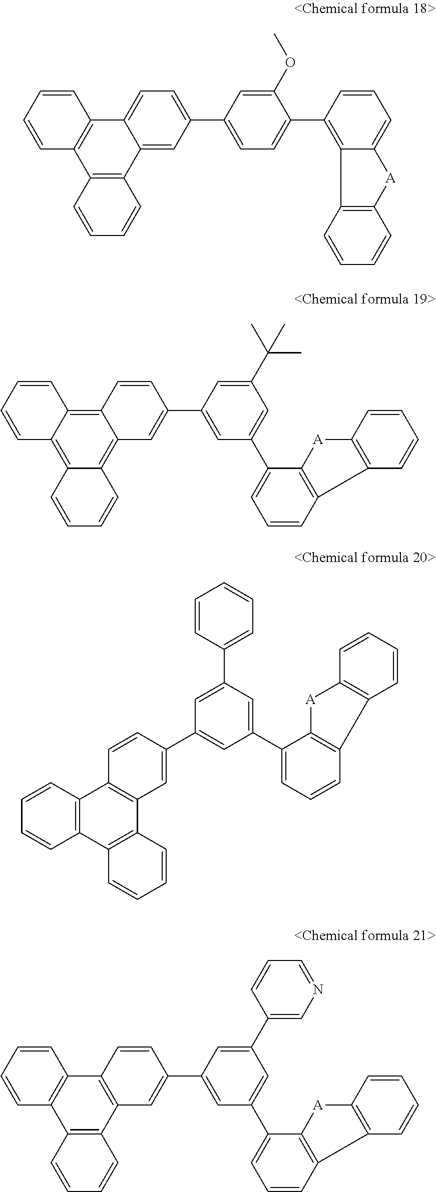 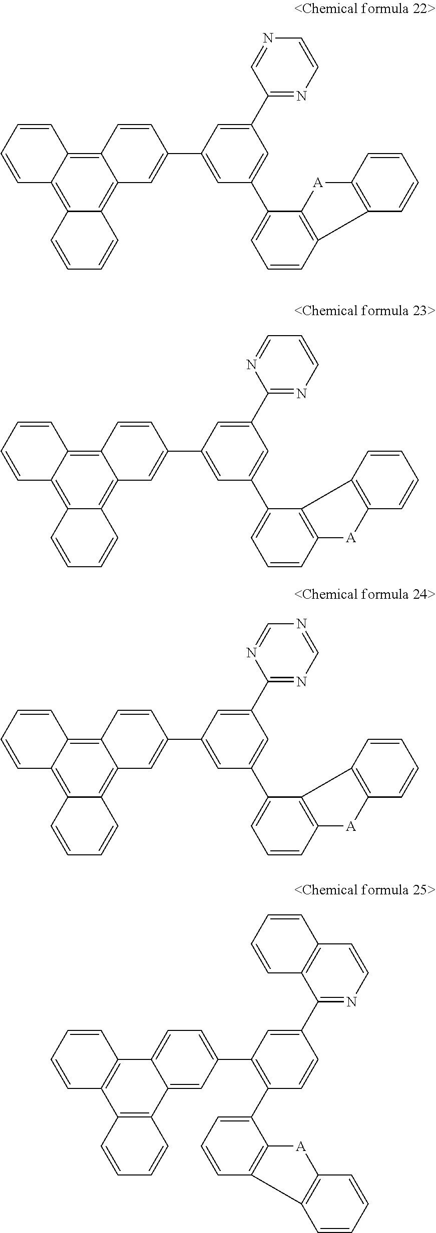 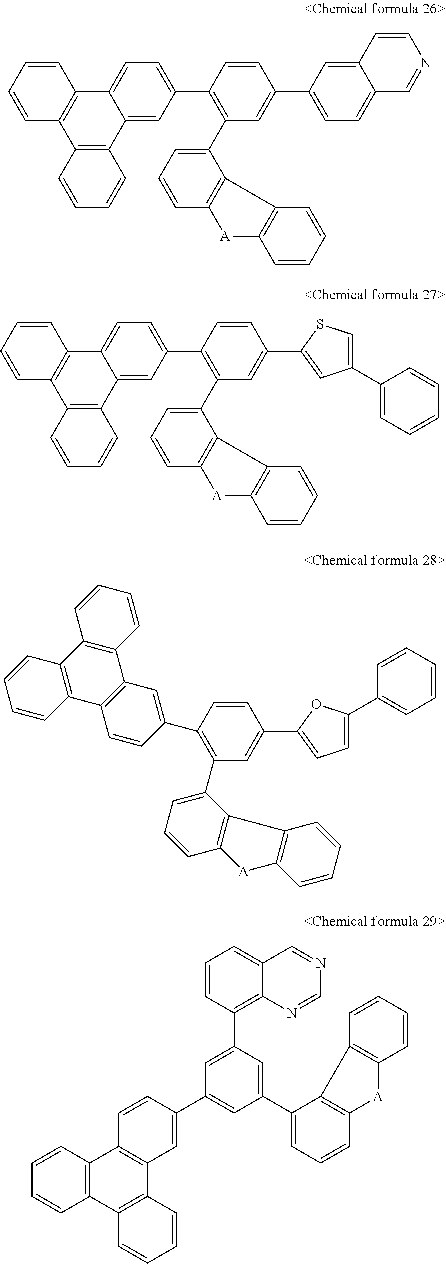 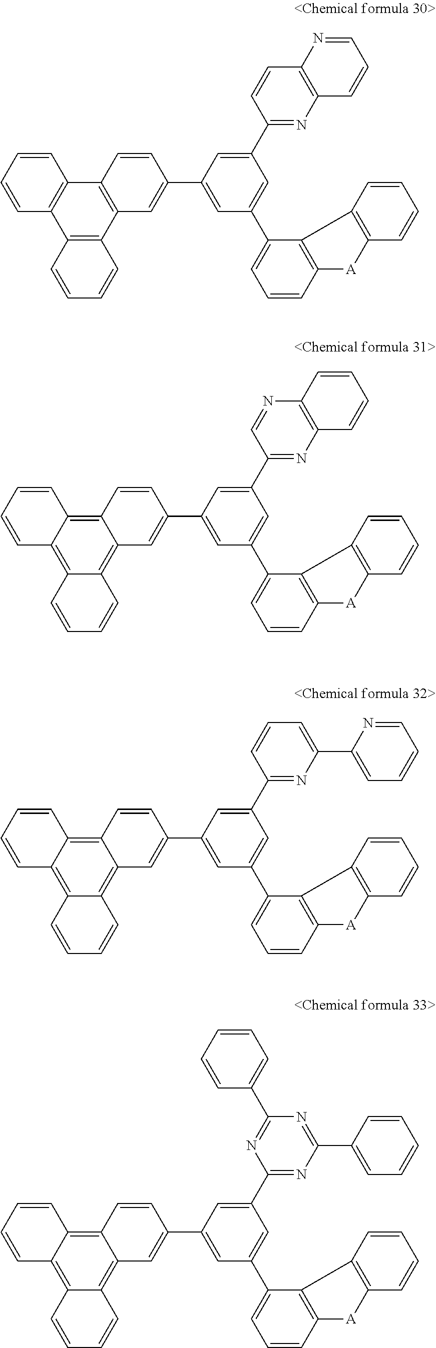 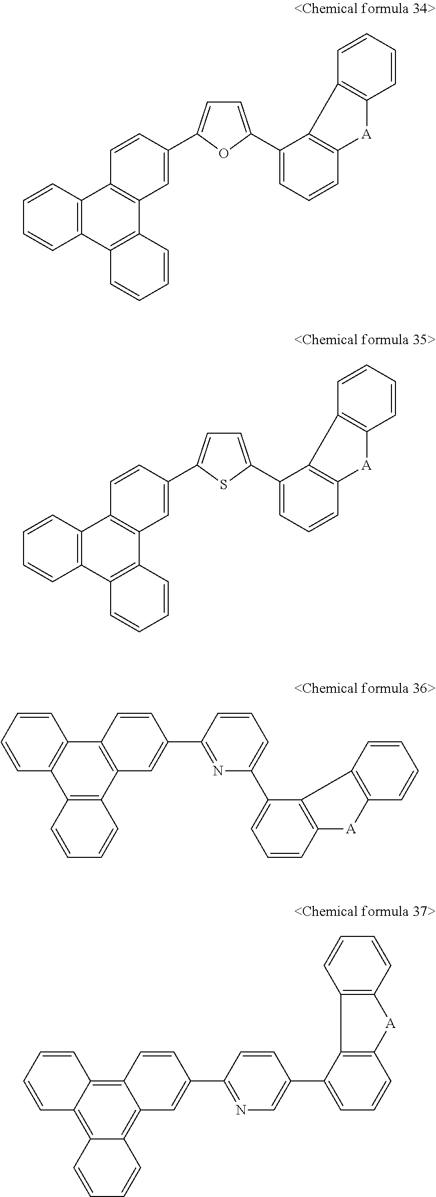 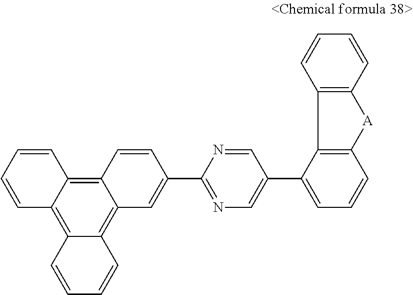 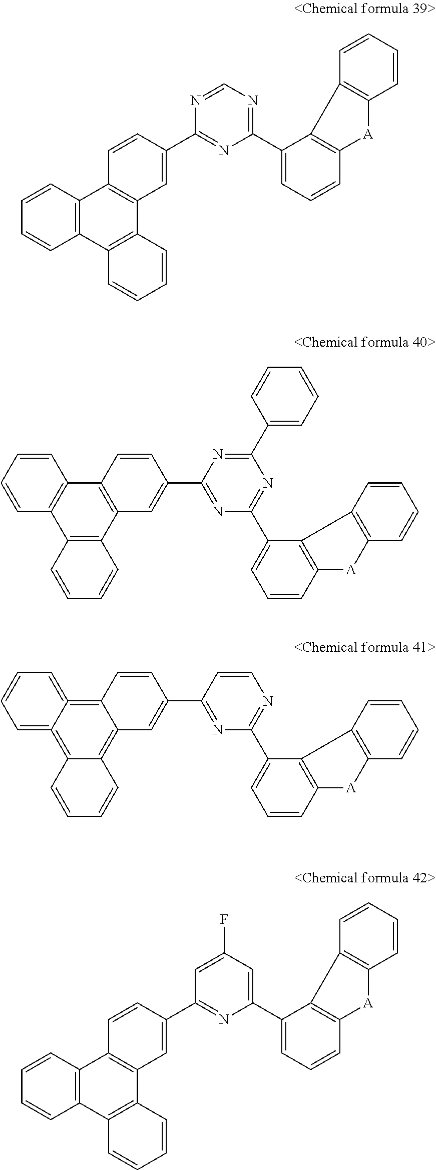 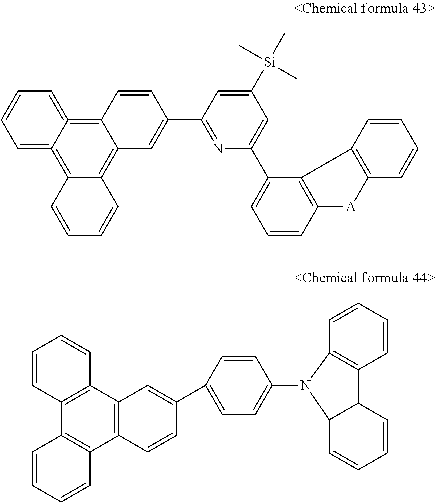
wherein A is N or S.

8. The organic light emitting diode of claim 1, wherein the second electron-transporting host comprises at least one selected from the group consisting of compounds expressed by chemical formulas 45 to 48 below, 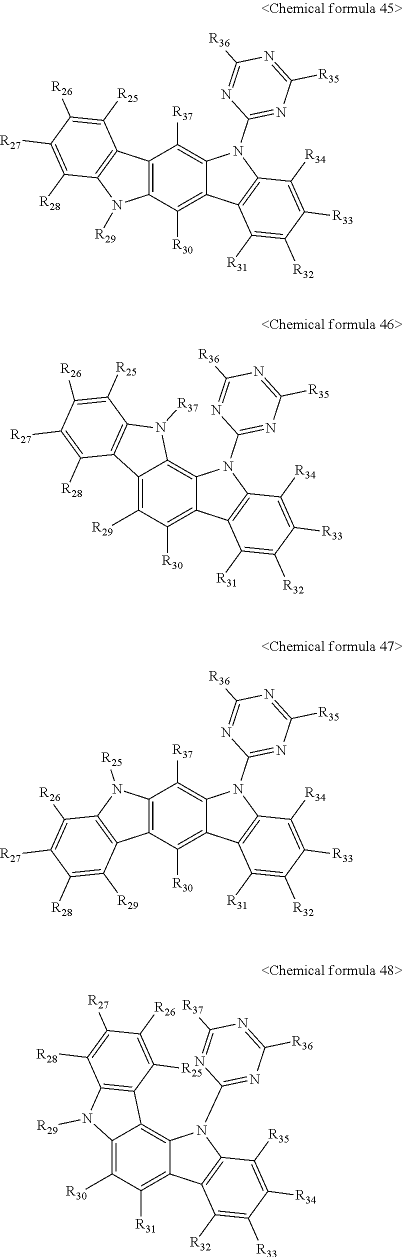
wherein in the chemical formulas 45 to 48, each of R₂₅ to R₃₇ is independently one selected from the group consisting of a hydrogen atom, a cyano group, a hydroxyl group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group.

9. The light emitting display diode of claim 1, wherein the phosphorescent guest comprises a compound expressed by chemical formula 49: 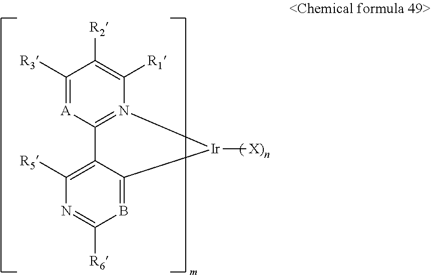
wherein in the chemical formula 49, A is —C(R′₄)— or —N—;
B is —C(R′₇)— or —N—;
each of R′₁ to R′₇ is independently one selected from the group consisting of a hydrogen atom, a cyano group, a hydroxy group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group;
two or more substitutes selected among R′₁ to R′₄, R′₄ and R′₅, and R′₆ and R′₇ are connected to each other to form saturated or unsaturated carbon chain or saturated or unsaturated hetero chain;
X is a monovalence anionic bidentate ligand;
m is 2 or 3, n is 0 or 1, and the sum of m and n is 3.

10. The organic light emitting diode of claim 1, wherein the phosphorescent guest comprises at least one selected from the group consisting of compounds expressed by chemical formulas 50 and 51 below: 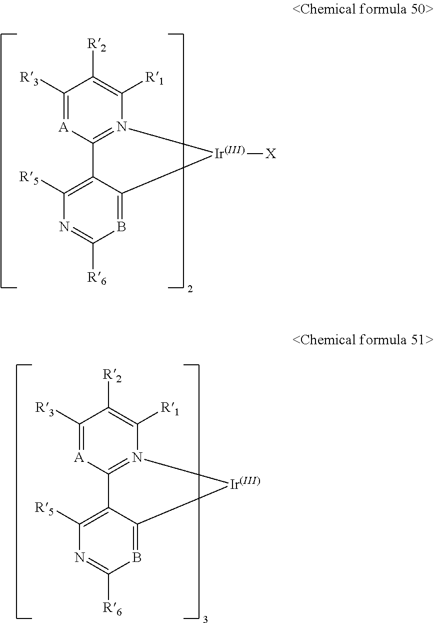
wherein in the chemical formulas 50 and 51, A is —C(R′₄)— or —N—;
B is —C(R′₇)— or —N—;
each of R′₁ to R′₇ is independently one selected from the group consisting of a hydrogen atom, a cyano group, a hydroxy group, a nitro group, a halogen atom, a substituted or unsubstituted C₁-C₂₀ alkyl group, a substituted or unsubstituted C₁-C₂₀ alkoxy group, a substituted or unsubstituted C₆-C₂₀ aryl group, a substituted or unsubstituted C₇-C₂₀ aryl alkyl group, a substituted or unsubstituted C₂-C₂₀ alkyl alkoxy group, a substituted or unsubstituted C₇-C₂₀ aryl alkoxy group, a substituted or unsubstituted C₆-C₂₀ aryl amino group, a substituted or unsubstituted C₁-C₂₀ alkyl amino group, a substituted or unsubstituted C₆-C₂₀ aryl amino group, and a substituted or unsubstituted C₂-C₂₀ heterocyclic group;
two or more substitutes selected among R′₁ to R′₄, R′₄ and R′₅, and R′₆ and R′₇ are connected to each other to form saturated or unsaturated carbon chain or saturated or unsaturated hetero chain;
X is a monovalence anionic bidentate ligand;
m is 2 or 3, n is 0 or 1, and the sum of m and n is 3.

11. The organic light emitting diode of claim 9, wherein X is one selected from the group consisting of compounds expressed by chemical formulas 52 to 63 below:

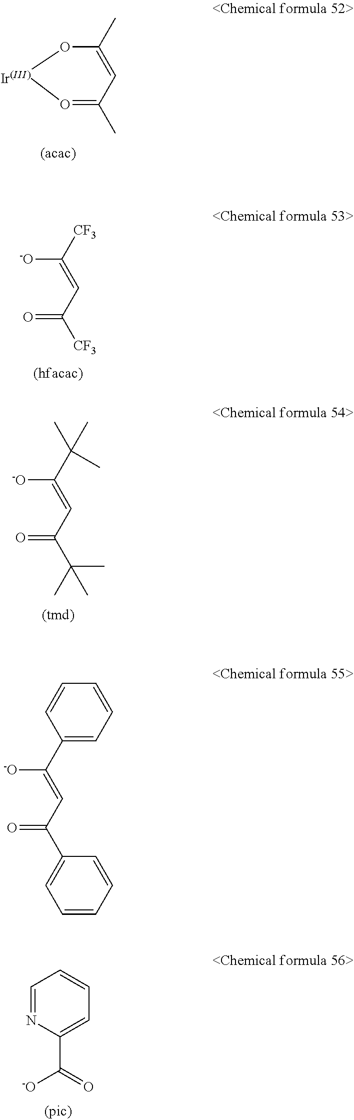

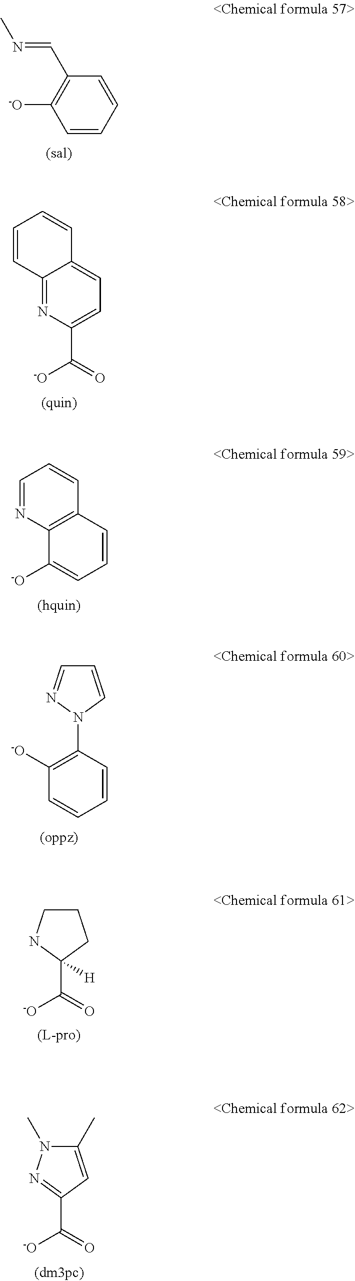

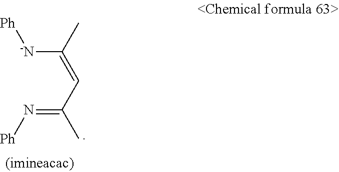

12. The organic light emitting diode of claim 10, wherein X is one selected from the group consisting of compounds expressed by chemical formulas 52 to 63 below:

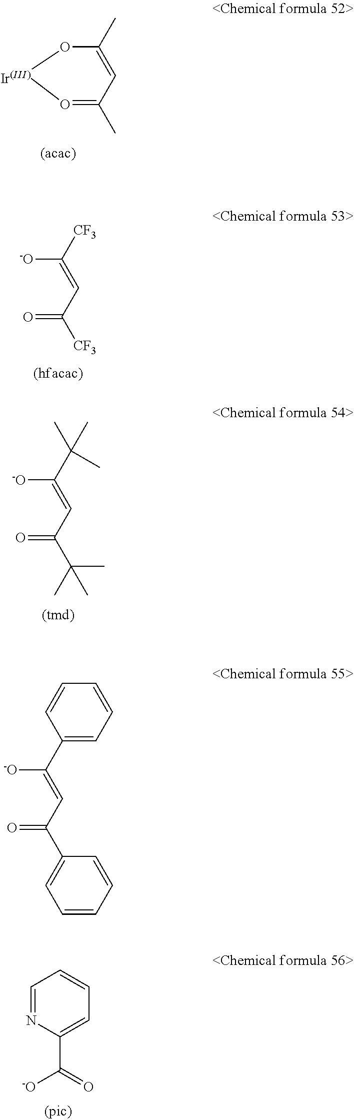

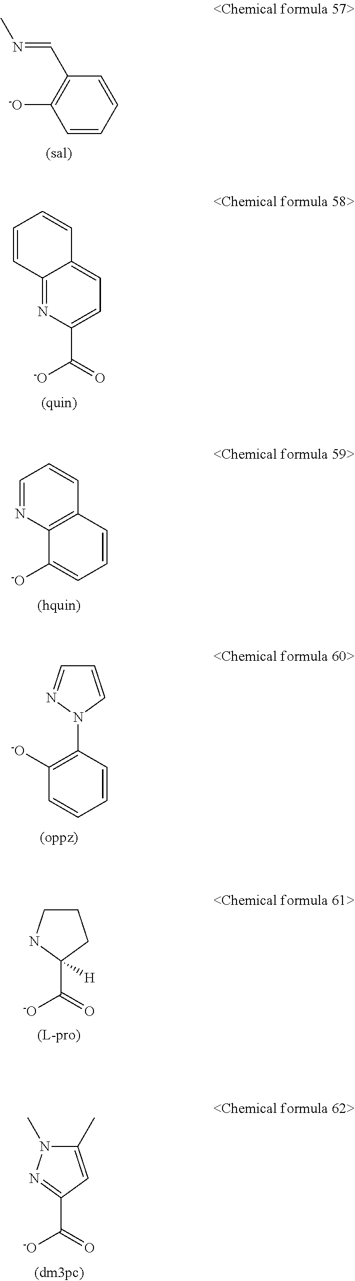

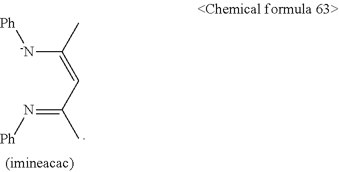

13. The organic light emitting diode of claim 1, wherein the organic layer comprises a hole injection layer, a hole transport layer, a light emitting layer, and an electron transport layer, and the light emitting layer comprises the first hole-transporting host, the second electron-transporting host, and the phosphorescent guest.

14. The organic light emitting diode of claim 1, wherein a first hole-transporting host content is equal to or higher than 50 wt % and equal to or lower than 78%, a second electron-transporting host content is equal to or higher than 10 wt % and equal to or lower than 40 wt %, and a phosphorescent guest content is equal to or higher than 1 wt % and equal to or lower than 20 wt %.
